(19) United States
(12) Patent Application Publication
(10) Pub. No.: US 2010/0039126 A1
(43) Pub. Date: Feb. 18, 2010

(54) NANOCHANNEL-BASED SENSOR SYSTEM FOR USE IN DETECTING CHEMICAL OR BIOLOGICAL SPECIES

(75) Inventors: Yu Chen, Boston, MA (US); Xihua Wang, Allston, MA (US); Agniezska Kalinowski, Pittsburgh, PA (US); Mi Hong, Quincy, MA (US); Pritiraj Mohanty, Los Angeles, CA (US); Shyamsunder Erramilli, Quincy, MA (US)

Correspondence Address: BAINWOOD HUANG & ASSOCIATES LLC, 2 CONNECTOR ROAD, WESTBOROUGH, MA, 01581, US

(73) Assignee: Trustees of Boston University, Boston, MA (US)

(21) Appl. No.: 12/464,665

(22) Filed: May 12, 2009

Related U.S. Application Data
(63) Continuation of application No. PCT/US2007/084046, filed on Nov. 8, 2007.
(60) Provisional application No. 60/859,630, filed on Nov. 17, 2006.

(51) Int. Cl. G01N 27/04; G01R 27/08

(52) U.S. Cl. 324/693; 977/957

(57) ABSTRACT

A sensor system for detecting a chemical or biological species includes a sensing element and a bias and measurement circuit. The sensing element includes nanochannels, each having an outer surface functionalized to chemically interact with the species to create a corresponding surface potential, and each having a sufficiently small cross section to exhibit a shift of a differential conductance characteristic into a negative bias operating region by a shift amount dependent on the surface potential. The bias and measurement circuit applies a bias voltage across two ends of the nanochannels sufficiently negative to achieve a desired dependence of the differential conductance on the surface potential, wherein the dependence has a steeply sloped region of high amplification substantially greater than a reference amplification at a zero-bias condition, thus achieving relatively high signal-to-noise ratio. The bias and measurement circuit converts the measured differential conductance into a signal indicative of presence or activity of the species of interest.

### STATEMENT OF FEDERAL RIGHTS

The invention was made with Federal support under Contract No. W81XWH-04-1-0578 awarded by the Department of the Army and Contract No. DBI-0242697 awarded by the National Science Foundation. The Government has certain rights in the invention.

### BACKGROUND

The present invention is related to the field of sensors used to sense chemical or biological species, for example in an analyte solution.

In the field of chemical and biological sensors, it is known to employ so-called “nanowires” or similar small-scale electrical devices as sensitive transducers to convert chemical activity of interest into corresponding electrical signals that accurately represent the chemical activity.

U.S. Pat. No. 7,129,554 of Lieber et al. describes nanosensors which may be utilized for such purposes. The nanosensors may consist of one or more nanowires which may have a tubular form. The nanowires can be functionalized at their surface to permit interaction with adjacent molecular entities, such as chemical species, and the interaction induces a change in a property (such as conductance) of the functionalized nanowire. This behavior serves as the basis for nanochannel-based nanosensors.

### SUMMARY

For many sensing applications, it is beneficial to employ sensors having high sensitivity to a species of interest. Sensors with high sensitivity can be used to detect much smaller amounts or concentrations of the species, which may be necessary or desirable in some applications, and/or such sensors can provide a high signal-to-noise ratio and thus improve the quality of measurements that are taken using the sensor.

Disclosed is a sensor system for detecting a chemical or biological species in an analyte which includes a sensing element and a bias and measurement circuit. The sensing element includes one or more nanochannels, each nanochannel having an outer surface functionalized to chemically interact with the species to create a corresponding surface potential, and each nanochannel having a sufficiently small cross section to exhibit a shift of a differential conductance characteristic into a negative bias operating region by a shift amount dependent on the surface potential or the surface charge. In one embodiment, each nanochannel has a cross section of about 100 nm by 150 nm or smaller. Functionalization can be done according to standard protocols, including for example the use of enzymes such as urease (for urea sensing) or glucose oxidase (for glucose sensing), or antibodies and antigens.

The bias and measurement circuit applies a bias voltage across two ends of the nanochannels, the bias voltage being sufficiently negative to achieve a desired dependence of the differential conductance of the sensing element on the surface potential of the nanochannels. This dependence has a steeply sloped region of high amplification which is substantially greater than a reference amplification exhibited by the sensing element at a zero-bias condition, thus achieving relatively high signal-to-noise ratio. The bias and measurement circuit measures the differential conductance of the sensing element and converts the measured differential conductance into a signal indicative of presence or activity of the species, for example by using a look-up table or alternative conversion mechanism reflecting a prior calibration operation.

### BRIEF DESCRIPTION OF THE DRAWINGS

The foregoing and other objects, features and advantages will be apparent from the following description of particular embodiments of the invention, as illustrated in the accompanying drawings in which like reference characters refer to the same parts throughout the different views. The drawings are not necessarily to scale, emphasis instead being placed upon illustrating the principles of various embodiments of the invention.

FIG. 1 is a schematic diagram illustrating the use of a sensor device used to detect species in an analyte according to an embodiment of the invention;

FIG. 2 (consisting of parts 2(a)-2(d)) depicts a nanochannel-based sensing element in the circuit of FIG. 1;

FIG. 3 depicts a sensor employing an array of nanochannels;

FIG. 4 (consisting of parts 4(a)-4(e)) is a set of graphs depicting electrical characteristics of a nanochannel-based sensing element;

FIG. 5 is a schematic of a bias/measurement circuit;

FIG. 6 (consisting of parts 6(a)-6(b)) is a set of graphs of measured differential conductance of a biomolecular sensor as respective functions of time and anitbiotin concentration;

FIG. 7 (consisting of parts 7(a)-7(d)) is a set of graphs illustrating measured differential conductance of a biomolecular sensor as functions of time and sensor bias voltage;

FIG. 8 is a graph illustrating measured differential conductance of a urea sensor;

FIG. 9 (consisting of parts 9(a)-9(b)) is a set of graphs illustrating measured differential conductance change of a glucose sensor.

### DETAILED DESCRIPTION

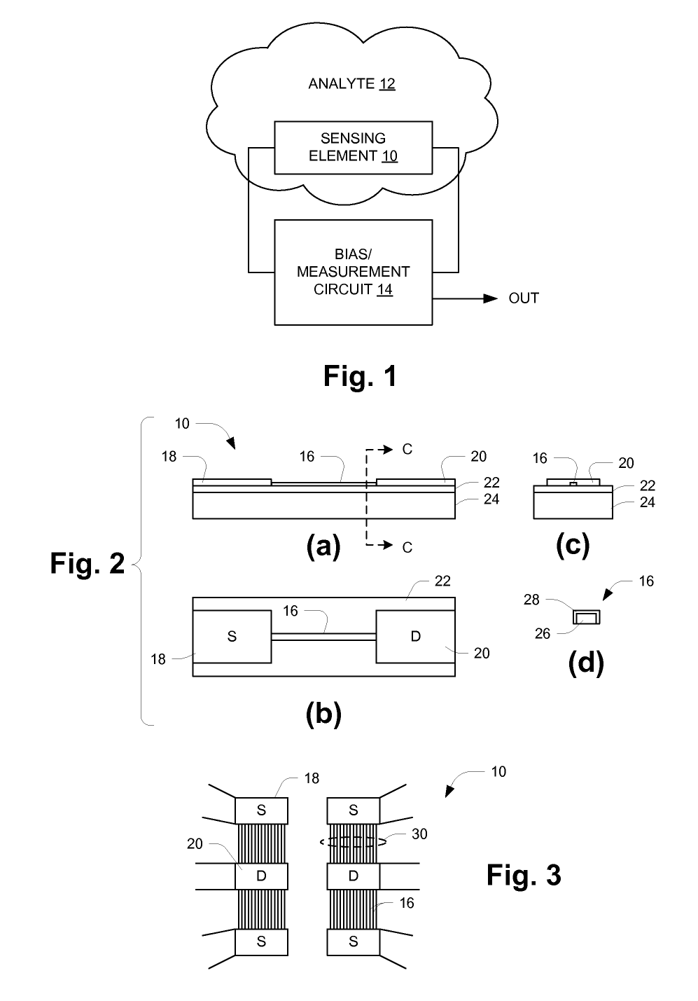

In FIG. 1, a sensing element 10 is exposed to chemical or biological species in an analyte solution (analyte) 12. The sensing element 10 has connections to a bias/measurement circuit 14 that provides a bias voltage to the sensing element 12 and measures the value of “differential conductance” (small-signal change of conductance with respect to bias voltage) of the sensing element 12. The differential conductance of the device is measured by applying a small modulation of bias voltage to generate a value of an output signal (OUT) that provides information about the chemical or biological species of interest in the analyte 12, for example a simple presence/absence indication or a multi-valued indication representing a concentration of the species in the analyte 12.

The sensing element 12 includes one or more elongated conductors of a semiconductor material such as silicon, which may be doped with impurities to achieve desired electrical characteristics as generally known in the art. Furthermore, the sensing elements are “nanoscale” channels, which in this context means that the dimensions of a channel are sufficiently small that chemical/electrical activity on its surface have a much more pronounced effect on electrical operation than in larger devices. Such nanoscale channels are referred to as “nanochannels” herein. In one embodiment, the sensing element 12 has one or more constituent nanochannels having a cross-sectional dimension of less than about 150 nm (nanometers), and even more preferably less than about 100 nm.

As described in more detail below, the surface of the sensing element 12 is “functionalized” by a series of chemical reactions to incorporate receptors or sites for chemical interaction with the species of interest in the analyte 12. As a result of this interaction, the charge distribution or “surface potential” of the surface of the sensing element 12 changes in a corresponding manner, and this change of surface potential alters the conductivity of the sensing element 10 in a way that is detected and measured by the bias/measurement circuit 14. Thus, the sensing element 12 is a field-effect device, i.e., its channel conductivity is affected by a localized electric field related to the surface potential or surface charge density. Measured differential conductance values are converted into values representing the property of interest (e.g., the presence or concentration of species), based on known relationships as may have been established in a separate calibration procedure, for example.

FIG. 2 shows a sensing element 10 according to one embodiment. As shown in the side view of FIG. 2(a), a silicon nanochannel 16 extends between a source (S) contact 18 and a drain (D) contact 20, all formed on an insulating oxide layer 22 above a silicon substrate 24. FIG. 2(b) is a top view showing the narrow elongated nanochannel 16 extending between the wider source and drain contacts 18, 20, which are formed of a conductive material such as gold-plated titanium for example. FIG. 2(c) shows the cross-sectional view in the plane C-C of FIG. 2(a). FIG. 2(d) shows the cross section of the nanochannel 16 in more detail. In the illustrated embodiment, the nanochannel 16 includes an inner silicon member 26 and an outer oxide layer 28 such as aluminum oxide.

FIG. 3 shows a sensing element 10 employing an array of nanochannels 16, which in the illustrated embodiment are arranged into four sets 30, each set including approximately twenty parallel nanochannels 16 extending between respective source and drain contacts 18, 20. By utilizing arrays of nanochannels 16 such as shown, greater signal strength (current) is obtained and therefore the signal-to-noise ratio of the sensing element 10 is improved accordingly. To obtain fully parallel operation, the source contacts 18 are all connected together by separate electrical conductors, and likewise the drain contacts 20 are connected together by separate electrical conductors. Other configurations are of course possible. For example, each set 30 may be functionalized differently so as to react to different species which may be present in the analyte 12, enabling an assay-like operation. In such configurations, it is understood that each set 30 has separate connections to the bias/measurement circuit 14 to provide for independent operation.

The sensing element 10 may be made by a variety of techniques employing generally known semiconductor manufacturing equipment and methods. In one embodiment, Silicon-on-Insulator (SOI) wafers are employed. A starting SOI wafer may have a device layer thickness of 100 nm and oxide layer thickness of 380 nm, on a 600 μm boron-doped substrate, with a device-layer volume resistivity of 10-20 Ω-cm. After patterning the nanochannel channels and the electrodes in separate steps, the structure is etched out with an anisotropic reactive-ion etch (RIE). This process exposes the three surfaces (top and sides) of the silicon nanochannels 16 along the longitudinal direction, resulting in increased surface-to-volume ratio. Finally a layer of Al₂O₃ (5 to 15 nm thick) is grown by atomic layer deposition (ALD). Selective response to specific biological or chemical species is then realized by functionalizing the nanochannels 16 following standard protocols (examples below). In subsequent use, it may be convenient to employ a machined plastic flow cell fitted to the device and sealed with silicone gel, with the sensing element 10 bathed in a fluid volume of about 30 μL for example, connected to a syringe pump.

Additionally, the sensing element 10 may include other control elements or “gates” adjacent to the nanochannels 16. The use of a “top gate” is discussed below, which is a conductive element formed along the top of each nanochannel 16. Such a top gate may be useful for testing or characterization (as discussed below), and perhaps in some applications during use as well, to provide a way to tune the conductance of the sensing element in a desired manner. Alternatively, one or more “side gates” may be utilized for similar purposes, these being formed alongside each nanochannel 16 immediately adjacent to the oxide layer 28.

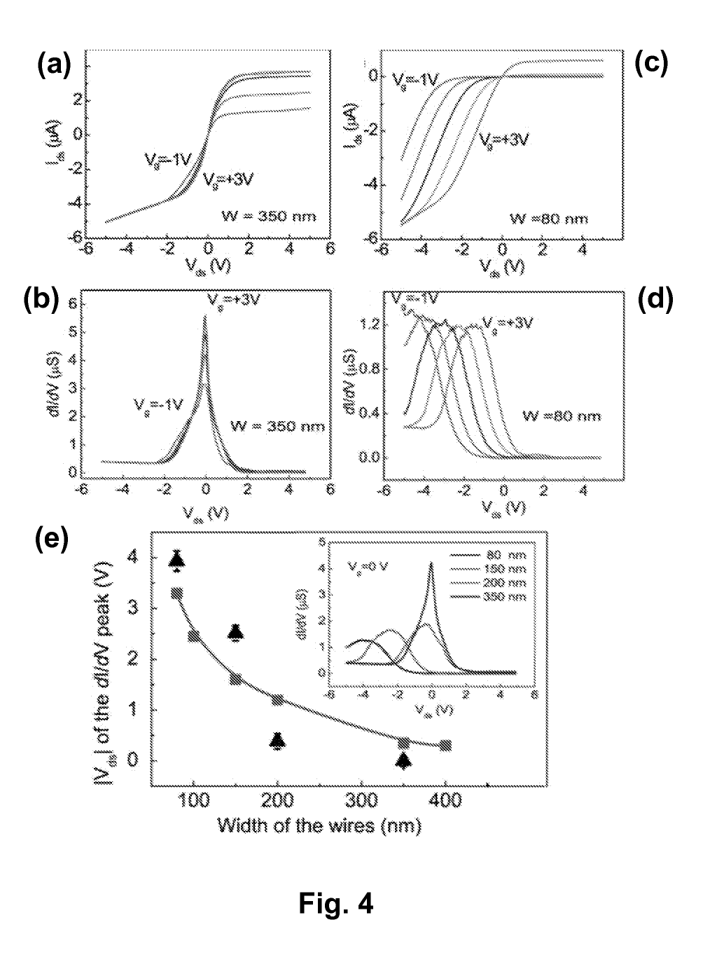

FIG. 4 shows salient electrical characteristics of a nanochannel-based sensing element 10, in all cases employing nanochannels 16 having a height or thickness of 100 nm. FIGS. 4(a) and 4(c) are curves of drain-source current I_{ds} versus drain-source voltage V_{ds} for different “gate” voltages V_{g} (explained below). The curves of FIG. 4(a) are for a device having nanochannels 16 of width W=350 nm, and the curves of FIG. 4(c) are for a device having nanochannels 16 of width W=80 nm. FIGS. 4(b) and 4(d) are curves of the “differential conductance” dI_{ds}/dV_{ds} versus V_{ds} for devices having width W of 350 nm and 80 nm respectively. FIG. 4(e) is a plot of the magnitude of the value of V_{ds} at which the peak of the dI_{ds}/dV_{ds} curve occurs as a function of width W

The curves of FIG. 4 are characteristic of a device similar to that of FIG. 2 but including a top gate located immediately above the nanochannel 16, separated from the silicon portion 26 by the aluminum oxide 28. The voltage on this gate was varied by an external DC source to simulate the effect of a change of surface potential caused by interaction of a functionalized nanochannel 16 with a species of interest, as explained in more detail below. In FIG. 4, current values are given in micro-Amperes (μA) and differential conductance in micro-Siemens (μS). It is believed that small changes in the conductance of the device (related to the inverse of the source-drain resistance) are best measured by considering the differential conductance dI/dV (e.g., as in FIGS. 4(b) and 4(d)) with the derivative taken at constant V_{g}. This method yields measurements at higher signal-to-noise ratio compared to using a digital method of computing derivatives from I_{ds} and V_{ds} separately.

Referring to FIGS. 4(a) and 4(b) for the 350 nm device, it is observed that the I_{ds}/V_{ds} characteristic of this device is substantially independent of the gate voltage V_{g} for large negative source-drain bias, V_{ds} less than −2V. As seen in FIG. 4(b), the peaks of the dI_{ds}/dV_{ds} curves for all values of V_{g} is in the immediate neighborhood of V_{ds}=0. The actual peak value of dI_{ds}/dV_{ds} increases by about a factor of two as V_{g} increases from −1 V to +3 V.

FIGS. 4(c) and 4(d) illustrate the markedly different characteristics of a sensing element 10 using nanochannels 16 having a width W of 80 nm. The I_{ds}/V_{ds} characteristic is much more heavily dependent on V_{g}. For example, the curves for one-volt increments of V_{g} are separated by approximately 0.7-volt increments of V_{ds}. FIG. 4(d) illustrates a corresponding separation of the peaks of the dI_{ds}/dV_{ds} curves. FIG. 4(e) captures the width dependence in a slightly different form, showing the relationship between the magnitude of V_{ds} at the dI_{ds}/dV_{ds} peak as a function of width W and, in the inset, the dI_{ds}/dV_{ds} curves themselves as a function of W for V_{g}=0.

It is believed that the spreading or shifting of the differential conductance peaks illustrated in FIGS. 4(c)-4(e) is due at least in part to the reduction of device size to below a certain threshold such that the effect of surface potential becomes much more pronounced. Mathematically, the surface-to-volume ratio of a generally rectangular solid is approximately inversely proportional to a transverse dimension such as W, and thus smaller (narrower) devices exhibit greater sensitivity to surface charge than larger (wider) devices. For the nanochannels 16, this sensitivity is in the form of differential conductivity as a function of surface charge or surface potential. Below a threshold width, which in the illustrated embodiment lies in the range of 150-200 nm, the locations of the peaks of the dI_{ds}/dV_{ds} curves are shifted to different values of V_{ds} as a function of the surface potential. Additionally, the appearance of the conductance peak might be related to the formation of a Schottky barrier by contact between the source/drain contacts 18, 10 (which are gold/titanium in one embodiment) and low-doped silicon of the nanochannels 16, in combination with the reduced cross-sectional dimensions of the nanochannels 16.

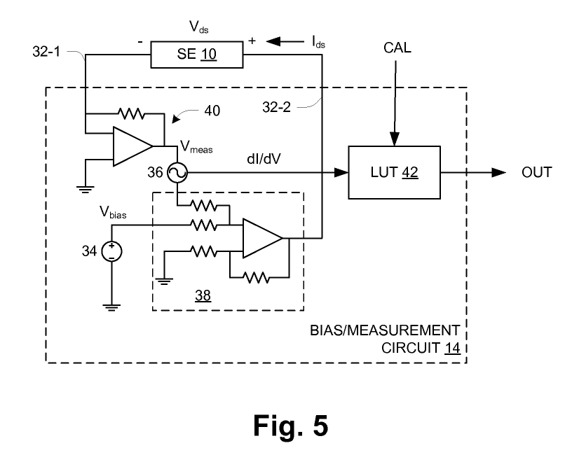

FIG. 5 illustrates a bias/measurement circuit 14 according to one embodiment. Conductors 32-1 and 32-2 are connected to first and second ends (e.g., source S and drain D respectively) of the sensing element (NE) 10. For convenient reference, the locations and polarities of V_{ds} and I_{ds} are shown. A DC source 34 generates a DC voltage V_{bias}, and an AC source 36 such as a lock-in amplifier generates a small AC measurement voltage Vₘₑₐₛ. These voltages are added together by a summing amplifier circuit 38. Amplifier circuit 40 completes the circuit between the sensing element (SE) 10 and the AC source 36, which generates a measure of dI_{ds}/dV_{ds} labeled dI/dV in FIG. 5. This value can be used by separate circuitry, such as a look-up table (LUT) 42 as shown, to convert the value of dI/dV into an output signal OUT whose value represents the quantity of interest with respect to the analyte 12 during use, as might be established in a separate calibration (CAL) procedure for example. Specific examples of such operation are given below.

The circuit of FIG. 1 may be useful in a variety of sensing applications, ranging from simple pH detection to the sensing of large proteins and even viruses. Several applications are described below as examples. It is to be understood that the descriptions are examples only, and that variations and alternatives may be employed as will be apparent to those skilled in the art based on the present disclosure.

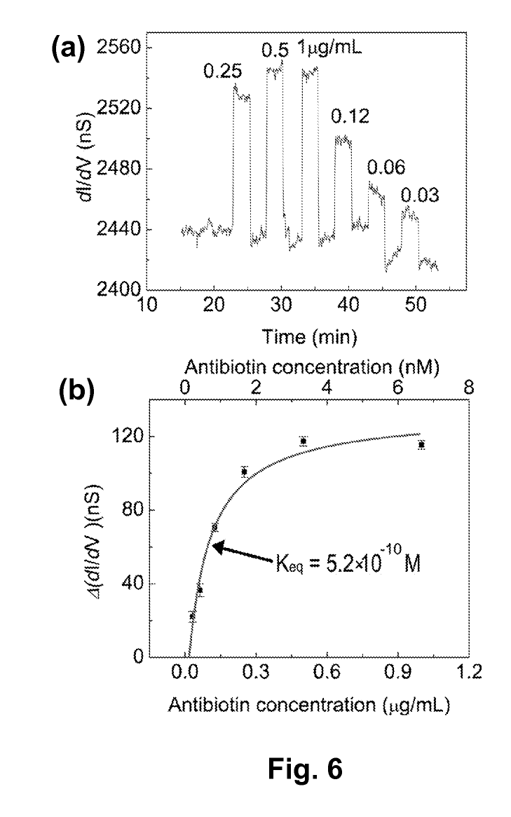

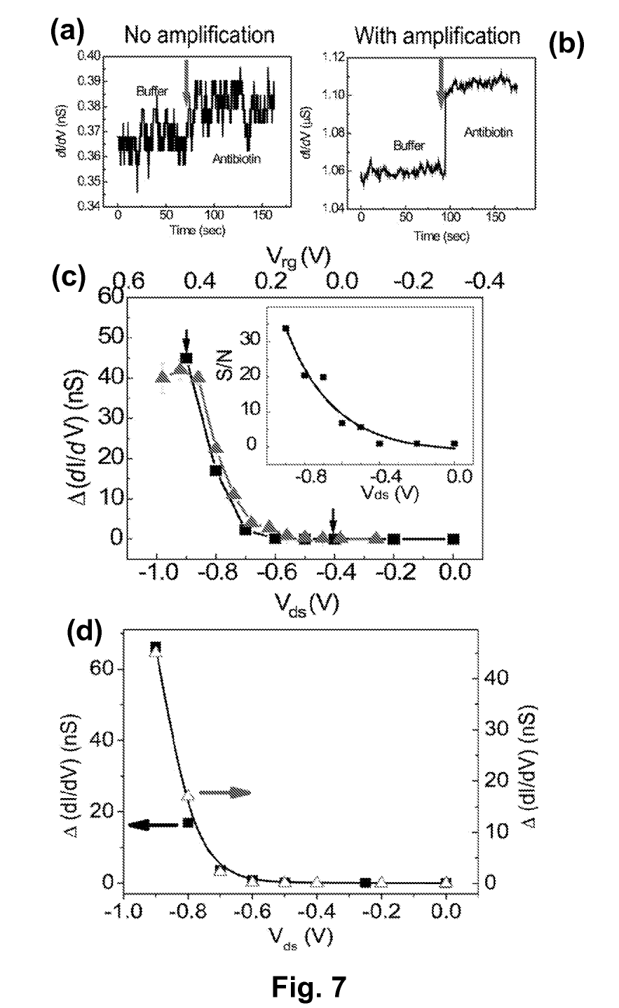

FIGS. 6 and 7 illustrate an application to detection of proteins or similar biomolecules. The underlying data was obtained in experiments in which the surface of the nanochannels 16 was functionalized with biotinylated bovine serum albumin (BSA), also referred to as “biotin”. The sensing element 10 was composed of 20 parallel nanochannels 16 of width W=250 nm, and biased at V_{ds}=−0.5 V. The analyte 12 consisted of a buffer solution containing 1 mM NaCl and 1 mM phosphate. FIG. 6(a) shows the value of dI/dV over time as the concentration of antibiotin in the buffer is varied. FIG. 6(b) shows a corresponding curve of the change of differential conductance (ΔdI/dV) as a function of antibiotin concentration, where the “change” is the difference between a measured value of dI/dV at the specified concentration and a measured value of dI/dV for the buffer solution itself (no antibiotin present). It can be shown that the dissociation constant K_{eq} for the binding reaction can be derived from these data.

FIG. 7 shows additional data of interest. FIGS. 7(a) and 7(b) each show dI/dV as a function of time, first for the buffer itself (“buffer”) and then for the buffer with 100 ng/mL of antibiotin (“antibiotin”). FIG. 7(a) exhibits operation at a bias voltage V_{ds} of −0.4 V, whereas FIG. 7(b) exhibits operation at a bias voltage V_{ds} of −0.9 V. It can be seen that operation at the bias voltage of −0.9 V exhibits substantially greater signal-to-noise ratio, due to the greater sensitivity or “amplification” that results from the above-described shifting of the dI/dV. FIG. 7(c) shows the differential conductance change introduced by biotin (1) at different values of V_{ds} at a constant reference gate voltage V_{rg}=0.3 (squares and bottom scale), and (2) at different values of V_{rg} and a constant V_{ds}=0 (triangles and top scale). The inset shows the signal-to-noise ratio of the device as a function of V_{ds}. FIG. 7(d) superimposes two curves, one showing the change of differential conductance versus V_{ds} caused by 5 mV of change of the reference gate voltage V_{rg} (squares and left scale), and the other showing the change of differential conductance versus V_{ds} caused by 100 ng/mL of antibiotin solution (triangles and right scale). This data suggests that the change of surface potential caused by 100 ng/mL of antibiotin is similar in effect to a change of about 7.2 mV of reference gate voltage. Relationships such as shown in FIG. 7(d) provide a basis for calibration as discussed above.

It will be appreciated that the biotin-antibiotin binding mechanism can be replaced by other molecular binding mechanisms depending on the biomolecule of interest. In order to exploit different binding mechanisms, it is necessary to functionalize the surface of the nanochannels 16 accordingly (i.e., to deposit material that will provide the desired binding locations and activity).

As conceived, the disclosed sensor can be applied in the field of genomics, for detecting nucleic acid sequences, in the field of proteomics for detecting proteins and peptides, and in the field of metabolomics for detecting metabolites and small molecules.

Another application of the disclosed sensor is in the detection of urea in samples. In one experiment, a sensing element 10 has an array of twenty parallel nanochannels 16, each wire 150 nm wide, 100 nm thick, and 6 μm long. The device is covered with 8 nm of Al₂O₃ grown by atomic layer deposition. The surface is first modified by treatment with (3-Aminopropyl)Triethoxysilane (APTES) (3% in ethanol with 5% water). The surface is then functionalized by depositing 2% urease in 20 mM NaCl solution (5% glycerol, 5% BSA) and maintaining in glutaraldehyde vapor for 40 minutes, then air-drying. Urea samples are in 50 mM NaCl solution.

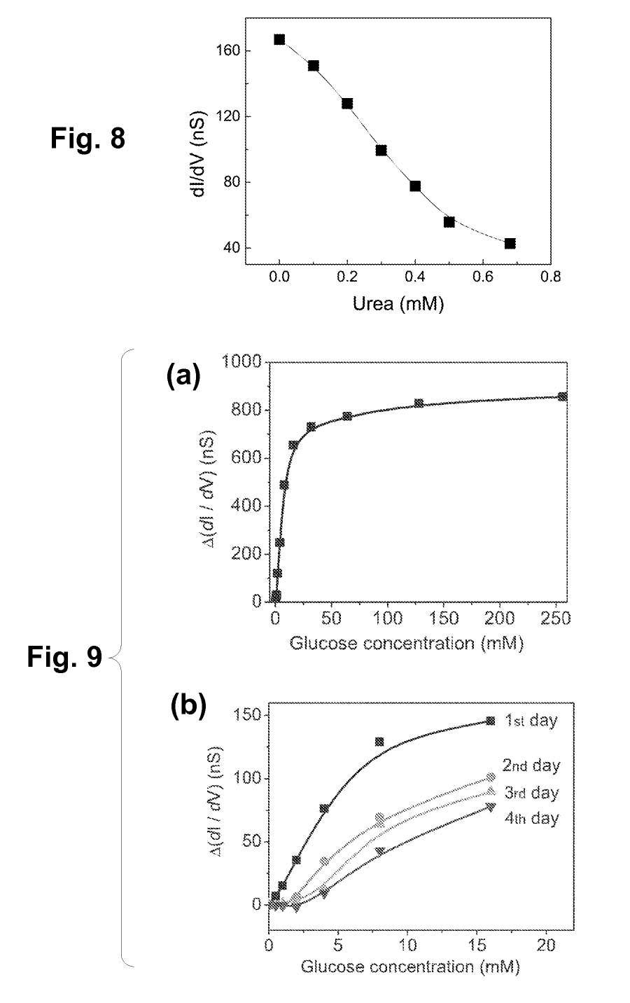

FIG. 8 shows results for various concentrations of urea in solution. The device is biased at V_{ds}=−0.6 V. As shown, the differential conductance varies from about 160 nS to about 40 nS as the urea concentration increases from about 0.0 to about 0.7 mM.

It should be noted that the APTES-treated sensing element 10 itself can be used as a pH sensor. In experiments there has been discovered an almost linear negative relationship between dI/dV and pH, with dI/dV ranging from 380 nS to 350 nS as pH changes from 2 to 10.

The disclosed sensor is also applicable to the detection of glucose in samples. In one experiment, the oxide-covered nanochannels 16 were functionalized with glucose oxidase deposited in acetic chloride (50 mM) buffer solution (5% glycerol, 5% BSA, pH 5.1). Glucose samples were in solution with 50 mM NaCl and 50 mM of potassium ferricyanide.

FIG. 9 shows the results for various concentrations of glucose in solution. FIG. 9(a) shows a saturation effect for concentrations above about 10-20 mM. FIG. 9(b) shows the performance of the device over several days. As is evident, device performance degrades over time, which may be due to deactivation of the glucose oxidase enzyme on the surface. Such changes in device performance over time should generally be given consideration in uses of the device.

What is claimed is:

1. A sensor system for detecting a chemical or biological species in an analyte, comprising:
a sensing element including one or more nanochannels, each nanochannel having a minimum of two ends and having an outer surface functionalized to chemically interact with the species to create a corresponding surface potential on the outer surface of the nanochannel, each nanochannel having a geometric shape of sufficiently small cross section to exhibit a shift of a differential conductance characteristic into a negative bias operating region by a shift amount being dependent on the surface potential; and
a bias and measurement circuit system operative (1) to apply a bias voltage across two ends of the nanochannels, the bias voltage being sufficiently negative to achieve a desired dependence of the differential conductance of the sensing element on the surface potential of the nanochannels, the desired dependence having a steeply sloped region of high amplification substantially greater than a reference amplification exhibited by the sensing element at a zero-bias condition, and (2) to measure the differential conductance of the sensing element and to convert the measured differential conductance into a signal indicative of presence or activity of the species;
wherein an electrically parallel array of three-dimensionally structured nanochannels increase the surface to volume ratio and thereby the sensitivity of the nanochannels, and wherein side and top gates allow programmable control of the surface potential and programmable control of the surface functionalization.

2. A sensor system according to claim 1, wherein the bias voltage has a magnitude of greater than 0.5 volts.

3. A sensor system according to claim 1, wherein the high amplification is at least two times greater than the reference amplification.

4. A sensor system according to claim 3, wherein the high amplification is at least ten times greater than the reference amplification.

5. A sensor system according to claim 1, wherein the species comprises glucose and the outer surface of the material element is functionalized with glucose oxidase.

6. A sensor system according to claim 1, wherein the species comprises urea and the outer surface of the sensing element is functionalized with urease.

7. A sensor system according to claim 1, wherein the species comprises a biomolecule and the outer surface of the sensing element is functionalized with biotin.

8. A sensor system according to claim 1, wherein the sensing element comprises one or more arrays of the nanochannels, each array including a plurality of electrically parallel, spaced-apart ones of the nanochannels.

9. A sensor system according to claim 1, wherein the cross section of each of the nanochannels is less than 100 nm×150 nm.

10. A sensor system according to claim 9, wherein the cross section of each of the nanochannels is less than 100 nm×100 nm.

11. A method of detecting a chemical or biological species in an analyte, comprising:
exposing a sensing element to the analyte, the sensing element including one or more elongated system nanochannels, each nanochannel having first and second ends and having an outer surface functionalized to chemically interact with the species to create a corresponding surface potential on the outer surface of the nanochannel, each nanochannel having a sufficiently small cross section to exhibit a shift of a differential conductance characteristic into a negative bias operating region by a shift amount being dependent on the surface potential;
applying a bias voltage across the first and second ends of the nanochannels, the bias voltage being sufficiently negative to achieve a desired dependence of the differential conductance of the sensing element on the surface potential of the nanochannels, the desired dependence having a steeply sloped region of high amplification substantially greater than a reference amplification exhibited by the sensing element at a zero-bias condition; and
measuring the differential conductance of the sensing element and converting the measured differential conductance into a signal indicative of presence or activity of the species.

12. A method according to claim 11, wherein the bias voltage has a magnitude of greater than 0.5 volts.

13. A method according to claim 11, wherein the high amplification is at least two times greater than the reference amplification.

14. A method according to claim 13, wherein the high amplification is at least ten times greater than the reference amplification.

15. A method according to claim 11, wherein the species comprises glucose and the outer surface of the material element is functionalized with glucose oxidase.

16. A method according to claim 11, wherein the species comprises urea and the outer surface of the material element is functionalized with urease.

17. A method according to claim 11, wherein the species comprises a biomolecule and the outer surface of the material element is functionalized with biotin.

18. A method according to claim 11, wherein the sensing element comprises one or more arrays of the nanochannels, each array including a plurality of electrically parallel, spaced-apart ones of the nanochannels.

19. A method according to claim 11, wherein the cross section of each of the nanochannels is less than 100 nm×150 nm.

20. A method according to claim 19, wherein the cross section of each of the nanochannels is less than 100 nm×100 nm.

21. A sensor system according to claim 1, wherein the sensing element incorporates side and top gates to the nanochannels in order to modulate the surface potential of the nanochannels.

22. A sensor system according to claim 1, wherein the sensing element incorporates side and top gates to the nanochannels in order to programmatically control the surface functionalization.
